(19) United States
(12) Patent Application Publication
(10) Pub. No.: US 2025/0374662 A1
(43) Pub. Date: Dec. 4, 2025

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Nan WANG, Shanghai (CN)

(21) Appl. No.: 18/684,575

(22) PCT Filed: Aug. 24, 2021
(86) PCT No.: PCT/CN2021/114352

§ 371 Date: Feb. 7, 2025

(51) Int. Cl. H10D 84/83; H10D 30/00; H10D 30/01; H10D 62/832; H10D 62/85; H10D 64/01; H10D 64/66; H10D 64/68; H10D 84/01

(52) U.S. Cl. CPC H10D 84/832; H10D 30/0191; H10D 30/502; H10D 62/8325; H10D 62/8503; H10D 64/017; H10D 64/666; H10D 64/667; H10D 64/691; H10D 64/693; H10D 84/0135

(57) ABSTRACT

A semiconductor structure includes: a substrate; and gate-all-around transistors on the substrate. Each gate-all-around transistor includes: a discrete protrusion on the substrate; a channel structure layer spaced apart from and suspended on the protrusion, including channel layers longitudinally stacked at intervals along a direction perpendicular to a surface of the substrate, a distance between the protrusion and a channel layer adjacent to the protrusion being larger than a distance between adjacent channel layers along the direction perpendicular to the surface of the substrate; a gate structure crossing the channel structure layer and surrounding each channel layer in the channel structure layer; a gate dielectric layer between the gate structure and the channel layers, and between the gate structure and the protrusion; and source-drain doped regions on the protrusion at two sides of the gate structure and in contact with ends of each channel layer along an extension direction.

### TECHNICAL FIELD

The present disclosure generally relates to the field of semiconductor manufacturing technology and, more particularly, relates to a semiconductor structure and its fabrication method.

### BACKGROUND

With rapid development of semiconductor manufacturing technology, semiconductor devices are developing towards higher component density and higher integration. Semiconductor process nodes continue to decrease following a development trend of Moore's Law. As the most basic semiconductor devices, transistors are currently being widely used. Therefore, as the component density and integration level of semiconductor devices increase, to adapt to the reduction of process nodes, a channel length of a transistor needs to be continuously shortened.

To better adapt to the requirements of feature sizes scaling down, semiconductor processes have gradually begun to transition from planar transistors to three-dimensional transistors with higher efficiency, such as gate-all-around (GAA) transistors. In a gate-all-around gate transistor, a gate surrounds an area where a channel is located from all sides. Compared with a planar transistor, the gate of the gate-all-around transistor has stronger control over the channel and is able to better suppress short-channel effect.

However, leakage current of existing devices still needs to be improved.

### TECHNICAL PROBLEMS

The preset disclosure provides a semiconductor structure and its fabrication method, to reduce leakage current of a device.

### SUMMARY

To solve the above technical problems, the present disclosure provides a semiconductor structure. The semiconductor structure includes: a substrate; and gate-all-around transistors on the substrate. Each gate-all-around transistor includes: a discrete protrusion on the substrate; a channel structure layer spaced apart from and suspended on the protrusion, including channel layers arranged at intervals and longitudinally stacked along a direction perpendicular to a surface of the substrate, where a distance between the protrusion and one channel layer adjacent to the protrusion is larger than a distance between adjacent channel layers along the direction perpendicular to the surface of the substrate; a gate structure crossing the channel structure layer and surrounding each channel layer in the channel structure layer; a gate dielectric layer between the gate structure and the plurality of channel layers and between the gate structure and the protrusion; and source-drain doped regions on the protrusion at two sides of the gate structure. The gate structure includes work function layers surrounding surfaces of the plurality of channel layers. The work function layers are filled between the protrusion and the channel layer adjacent to the protrusion and between the adjacent channel layers. When forming an NMOS transistor, the work function layers are made of a material including a P-type work function material; and when forming a PMOS transistor, the work function layers are made of a material including an N-type work function material. The source-drain doped regions contact ends of each channel layer in the channel structure layer along an extension direction.

Another aspect of the present disclosure also provides a fabrication method of a semiconductor structure. In the method, a base substrate for forming MOS transistors is provided. The base substrate includes a substrate, discrete protrusions on the substrate; and a plurality of channel stack layers stacked on each protrusion. Each channel stack layer includes a sacrificial layer and a channel layer on the sacrificial layer. Sacrificial layers between the protrusion and one channel stack layer adjacent to the protrusion are used as first sacrificial layers. Sacrificial layers in channel stack layers above the first sacrificial layers are used as second sacrificial layers. A thickness of the first sacrificial layers is larger than a thickness of the sacrificial layers. A dummy gate structure is formed crossing the plurality of channel stack layers. Source-drain doped regions are formed in the channel stack layers on two sides of the dummy gate structure. The source-drain doped regions contact ends of each channel layer in the plurality of channel stack layers along the extending direction. After forming the source-drain doped regions, the dummy gate structure is removed to form a gate opening exposing the plurality of channel stack layer. The sacrificial layers in the plurality of channel stack layers are removed to form through grooves connected to the gate opening. The through grooves include first through grooves formed by removing the first sacrificial layers and second through grooves formed by removing the second sacrificial layers. A gate structure is formed in the gate opening. The gate structure includes work function layers surrounding surfaces of the channel layers and filled in the through grooves. When forming an NMOS transistor, the work function layers are made of a material including a P-type work function material; and when forming a PMOS transistor, the work function layers are made of a material including an N-type work function material.

### Effective Benefits

Compared to existing technologies, the present disclosure has following benefits. In the semiconductor structure provided by the present disclosure, the work function layers may surround the surfaces of the channel layers. When forming an NMOS transistor, the material of the work function layers may be a P-type work function material, thereby increasing the threshold voltage of the NMOS device. When forming a PMOS transistor, the material of the work function layers may be an N-type work function material, thereby increasing the threshold voltage of the PMOS device. Further, along the direction perpendicular to the surface of the substrate, the distance between the protrusions and the channel layers adjacent to the protrusions may be larger than the distance between adjacent channel layers. Correspondingly, the thickness of the work function layers filled between the protrusions and the channel layers adjacent to the protrusions may be larger than the thickness of the work function layers filled between adjacent channel layers. In the semiconductor field, when the work function layer materials are the same, usually when the work function layer is thicker, the adjustment effect on the threshold voltage of the device is more obvious. When the thickness of the work function layers filled between the protrusions and the channel layers adjacent to the protrusions is larger than the thickness of the work function layers filled between adjacent channel layers, compared with the device corresponding to the channel layers, the threshold voltage of the parasitic device corresponding to the protrusions may be higher, and the parasitic device may be less likely to be turned on, which is beneficial to reducing the bottom leakage current generated in the protrusions and improving the semiconductor structure performance.

In the fabrication method of the semiconductor structure provided by the present disclosure, the thickness of the first sacrificial layers may be larger than the thickness of the second sacrificial layers. When removing the first sacrificial layers to form the first through grooves and removing the second sacrificial layers to form the second through grooves, the height of the first through grooves may be larger than the second through grooves. When forming the gate structure, the work function layer may surround the surface of the channel layers and fill the through grooves. When forming an NMOS transistor, the material of the work function layers may be a P-type work function material, thereby increasing the threshold voltage of the NMOS device. When forming a PMOS transistor, the material of the work function layers may be an N-type work function material, thereby increasing the threshold voltage of the PMOS device. Further, since the height of the first through grooves may be larger than the second through grooves, the thickness of the work function layers filled in the first through grooves may be larger than the thickness of the work function layers filled in the second through grooves. In the semiconductor field, when the work function layer materials are the same, usually when the work function layer is thicker, the adjustment effect on the threshold voltage of the device is more obvious. Since the thickness of the work function layers filled in the first through grooves is larger than the thickness of the work function layers filled in the second through grooves, compared with the device corresponding to the channel layers, the threshold voltage of the parasitic device corresponding to the protrusions may be higher, and the parasitic device may be less likely to be turned on, which is beneficial to reducing the bottom leakage current generated in the protrusions and improving the semiconductor structure performance.

### BRIEF DESCRIPTION OF THE DRAWINGS

FIG. 1 illustrates a semiconductor structure.

FIG. 2 to FIG. 3 illustrate an exemplary semiconductor structure according to various disclosed embodiments of the present disclosure.

FIG. 4 to FIG. 16 illustrate structures corresponding to certain stages of a fabrication method of a semiconductor structure according to various disclosed embodiments of the present disclosure.

### DETAILED DESCRIPTION

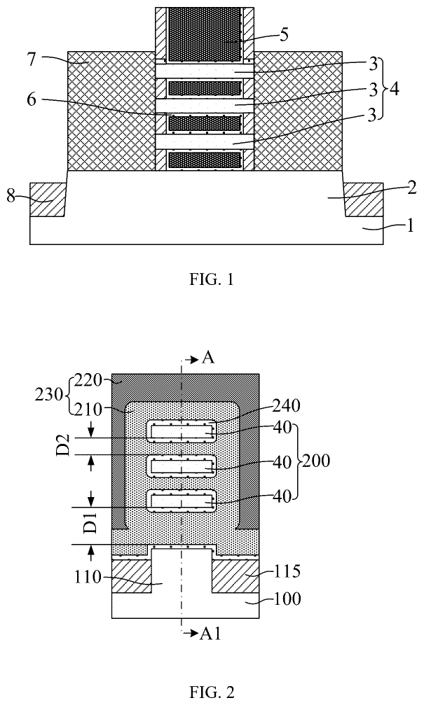

As described in the background, the leakage current in existing devices still needs to be improved. A semiconductor structure will be used as an example to analyze the reason of the leakage current that needs to be improved. FIG. 1 illustrates a semiconductor structure.

As shown in FIG. 1 where a semiconductor structure which is a gate-all-around transistor is used as an example, the semiconductor structure includes a base substrate including a substrate 1, discrete protrusions 2 on the substrate 1, and a suspended channel structure layer 4 arranged apart from the protrusions 2 and including a plurality of channel layers 3 arranged at intervals; a gate structure 5 crossing the channel structure layer 4 and surrounding the plurality of channel layers 3; gate dielectric layers 6 between the gate structure and the plurality of channel layers 3, and between the gate structure 5 and the protrusions 2; and source-drain doped regions 7 in the protrusions 2 at two sides of the gate structure 5 and contacting ends of the channel structure layers 4 along the extension direction.

The semiconductor structure usually further includes isolation layers 8 on the substrate 1 and surrounding the protrusions 2.

In the semiconductor structure, since the control ability of the gate structure 5 over the protrusions 2 is weaker than the control ability over the plurality of channel layers 3, leakage current is easily generated in the protrusions 2.

To reduce the leakage current generated in the protrusions 2, one method is to inject doping ions into the isolation layers 8 during the formation of the semiconductor structure. The doping type of the doping ions is different from the doping type of the source-drain doped regions 7. The doping ions are diffused into the protrusions 2, such that the protrusions 2 are doped with doping ions that are different from the doping type of the source-drain doping regions 7, to increase the difficulty of turning on the channels in the protrusions 2, thereby reducing the leakage current in the protrusions 2.

However, in the above method, it is difficult to control the diffusion of the doping ions in the isolation layers 8. Therefore, to allow enough doping ions to be diffused into the protrusions 2 to achieve the effect of reducing the leakage current, during the process of implanting the doping ions into the isolation layers 8, the required implantation dose is usually relatively large. However, ion implantation will cause random dopant fluctuation. Further, during the formation process of the semiconductor structure, before the gate structure is formed, sacrificial layers are formed between the adjacent channel layers 3 and between the channel layer 3 and the protrusions 2, to occupy the space for the gate structure. When the doping ions are also diffused into the sacrificial layers, the subsequent removal of the sacrificial layers may be affected.

The present disclosure provides a semiconductor structure to at least partially alleviate the above problems. In the semiconductor structure, the work function layers may surround the surfaces of the channel layers. When forming an NMOS transistor, the material of the work function layers may be a P-type work function material, thereby increasing the threshold voltage of the NMOS device. When forming a PMOS transistor, the material of the work function layers may be an N-type work function material, thereby increasing the threshold voltage of the PMOS device. Further, along the direction perpendicular to the surface of the substrate, the distance between the protrusions and the channel layers adjacent to the protrusions may be larger than the distance between adjacent channel layers. Correspondingly, the thickness of the work function layers filled between the protrusions and the channel layers adjacent to the protrusions may be larger than the thickness of the work function layers filled between adjacent channel layers. In the semiconductor field, when the work function layer materials are the same, usually when the work function layer is thicker, the adjustment effect on the threshold voltage of the device is more obvious. When the thickness of the work function layers filled between the protrusions and the channel layers adjacent to the protrusions is larger than the thickness of the work function layers filled between adjacent channel layers, compared with the device corresponding to the channel layers, the threshold voltage of the parasitic device corresponding to the protrusions may be higher, and the parasitic device may be less likely to be turned on, which is beneficial to reducing the bottom leakage current generated in the protrusions and improving the semiconductor structure performance.

The present disclosure also provides a fabrication method of a semiconductor structure. In the method, the thickness of the first sacrificial layers may be larger than the thickness of the second sacrificial layers. When removing the first sacrificial layers to form the first through grooves and removing the second sacrificial layers to form the second through grooves, the height of the first through grooves may be larger than the second through grooves. When forming the gate structure, the work function layer may surround the surface of the channel layers and fill the through grooves. When forming an NMOS transistor, the material of the work function layers may be a P-type work function material, thereby increasing the threshold voltage of the NMOS device. When forming a PMOS transistor, the material of the work function layers may be an N-type work function material, thereby increasing the threshold voltage of the PMOS device. Further, since the height of the first through grooves may be larger than the second through grooves, the thickness of the work function layers filled in the first through grooves may be larger than the thickness of the work function layers filled in the second through grooves. In the semiconductor field, when the work function layer materials are the same, usually when the work function layer is thicker, the adjustment effect on the threshold voltage of the device is more obvious. Since the thickness of the work function layers filled in the first through grooves is larger than the thickness of the work function layers filled in the second through grooves, compared with the device corresponding to the channel layers, the threshold voltage of the parasitic device corresponding to the protrusions may be higher, and the parasitic device may be less likely to be turned on, which is beneficial to reducing the bottom leakage current generated in the protrusions and improving the semiconductor structure performance.

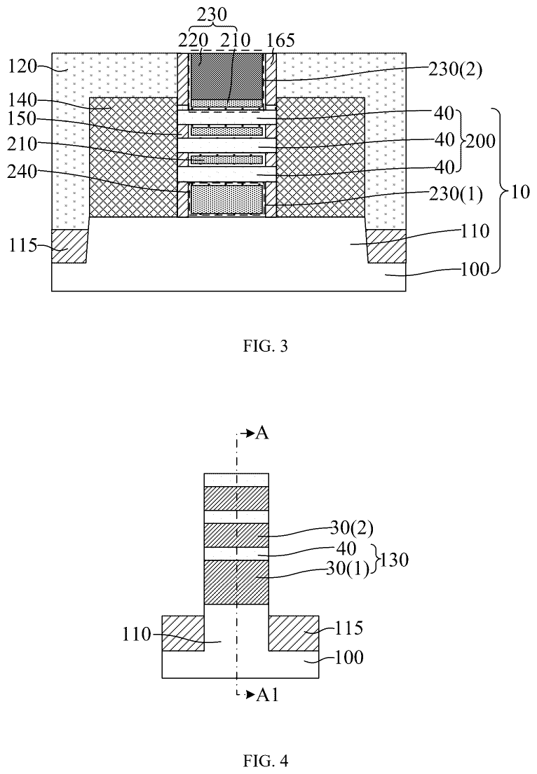

The embodiments by the present disclosure will be described in following with reference to drawings, to illustrate the implementation and benefits of the present disclosure. FIG. 1 and FIG. 2 illustrate structures of an exemplary semiconductor structure provided by one embodiment of the present disclosure. FIG. 2 is a cross-sectional view of the semiconductor structure at the position of the gate structure along a direction perpendicular to an extending direction of channel layers, and FIG. 3 is a cross-sectional view along an AA1 direction in FIG. 2.

As shown in FIG. 2 and FIG. 3, the semiconductor structure may include: a substrate 100; and gate-all-around transistors on the substrate 100. The gate-all-around transistors may include: discrete protrusions 110 on the substrate 100 and a channel structure layer 200 spaced apart from and suspended on each protrusions 110. The channel structure layer 200 may include a plurality of channel layers 40 arranged at intervals. The plurality of channel layers 40 may be vertically stacked along a direction perpendicular to a surface of the substrate 100. Along the direction perpendicular to the surface of the substrate 100, a distance between the protrusions 110 and channel layers 40 adjacent to the protrusions 110 may be larger than a distance between adjacent channel layers 40. The transistors may also include a gate structure 230 crossing the channel structure layer 200 and surrounding each channel layer 40 of the channel structure layer 200. The gate structure 230 may include work function layers 210 surrounding the surfaces of the plurality of channel layers 40. The work function layers 210 may fill between the protrusions 110 and channel layers 40 adjacent to the protrusions 110, and between adjacent channel layers 40. When forming an NMOS transistor, the material of the work function layers may be a P-type work function material, thereby increasing the threshold voltage of the NMOS device. When forming a PMOS transistor, the material of the work function layers may be an N-type work function material. The transistor may also include: gate dielectric layers 240 between the gate structure 230 and the plurality of channel layers 40, and between the gate structure 230 and the protrusions 110; and source-drain doped layers 140 on the protrusions 110 at two sides of the gate structure 230 and contact ends of each channel layer 40 in the channel structure layer 200 along the extending direction.

The substrate 100, the discrete protrusions 110 on the substrate 100, and the channel structure layer 200 that is spaced apart from the protrusions 110 and suspended may constitute the base substrate 10.

The substrate 100 may be used to provide a process platform for the formation of the semiconductor structure. In this embodiment, the substrate 100 may be used to provide a process platform for forming a gate-all-around (GAA) transistor.

In this embodiment, the substrate 100 may be a silicon substrate, that is, the substrate 100 may be made of a material including single-crystal silicon. In other embodiments, the substrate 100 may be made of a material including one or more of germanium, silicon germanium, silicon carbide, gallium nitride, gallium arsenide, or indium gallium. The substrate 100 may also be another type Of substrate including a silicon-on-insulator substrate or germanium-on-insulator substrate.

In this embodiment, the protrusions 110 and the substrate 100 may have an integrated structure, and the protrusions 110 and the substrate 100 may be made of the same material, which is silicon. In other embodiments, the material of the protrusions may be different from the material of the substrate, and the material of the protrusions may be other suitable materials, such as one or more of germanium, silicon germanium, silicon carbide, gallium nitride, gallium arsenide or indium gallium.

The semiconductor structure may further include an isolation layer 115 located on the substrate 100 and surrounding the protrusions 110. The isolation layer 115 may expose the channel structure layer 200. The isolation layer 115 may be used to isolate adjacent protrusions 110 and also used to isolate the substrate 100 and the gate structure 230. In this embodiment, the isolation layer 115 may be made of silicon oxide. In some other embodiments, the isolation layer 115 may be made of another insulating material including one or more of silicon oxide, silicon nitride, silicon oxynitride, or silicon germanium oxide.

In one embodiment, the top surface of the isolation layer 115 may be lower than the top surfaces of the protrusions 110. In other embodiments, the top surface of the isolation layer may be flush with the top surfaces of the protrusions.

The channel structure layer 200 may be used to provide a conductive channel of the field effect transistor. The plurality of channel layers 40 may provide a conductive channel of the field effect transistor.

In this embodiment, the stacking direction of the plurality of channel layers 40 may be perpendicular to the surface of the substrate 100.

In this embodiment, the plurality of channel layers 40 may be made of the same material as the protrusions 110. The plurality of channel layers 40 may be made of a material including Si, which is beneficial to improving the performance of the NMOS transistor. In other embodiments, when the semiconductor structure is a PMOS transistor, to improve the performance of the PMOS transistor, SiGe channel technology may be used, and the plurality of channel layers 40 may be made of a material including SiGe.

In this embodiment, the plurality of channel layers 40 may be made of the same material as the protrusions 110. In other embodiments, the plurality of channel layers 40 may be made of a material different from the protrusions 110.

In other embodiments, the plurality of channel layers 40 may be made of a material including one or more of germanium, silicon carbide, gallium nitride, gallium arsenide or indium gallium.

In one embodiment, the number of the plurality of channel layers 40 in the channel structure layer 200 may be three. In other embodiments, the number of the plurality of channel layers 40 in the channel structure layer 200, such as two, four, five, etc.

Along the direction perpendicular to the surface of the substrate 100, the distance between the protrusions 110 and the channel layers 40 adjacent to the protrusions 110 may be larger than the distance between the adjacent channel layers 40, such that the thickness of the work function layers 210 filled between the protrusions 110 and the channel layers 40 adjacent to the protrusions 110 may be larger than the thickness of the work function layers 210 filled between the adjacent channel layers 40.

In the semiconductor field, when the materials of the work function layers 210 are the same, usually when the work function layer 210 is thicker, the adjustment effect on the threshold voltage of the device is more obvious. When the thickness of the work function layers 210 filled between the protrusions 110 and the channel layers 40 adjacent to the protrusions 110 may be larger than the thickness of the work function layers 210 filled between the adjacent channel layers 40, compared with the device corresponding to the channel layers 40, the threshold voltage of the parasitic device corresponding to the protrusions 110 may be higher, and the parasitic device may be less likely to be turned on, which is beneficial to reducing the bottom leakage current generated in the protrusions 110 and improving the semiconductor structure performance.

In this embodiment, along the direction perpendicular to the surface of the substrate 100, the distance between the protrusions 110 and the channel layers 40 adjacent to the protrusions 110 may be a first distance D1, and the distance between the adjacent channel layers 40 may be a second distance D2.

It should be noted that the difference between the first distance D1 and the second distance D2 should not be too small. Otherwise, a difference between the thickness of the work function layers 210 filled between the protrusions 110 and the channel layers 40 adjacent to the protrusions 110 and the thickness of the work function layers 210 filled between the adjacent channel layers 40 may be non-obvious, and the work function layers 210 may not have a significant effect on adjusting the threshold voltage of the parasitic device corresponding to the protrusions 110, which is not able to make the threshold voltage of the parasitic device significantly larger than the threshold voltage of the device corresponding to the plurality of channel layers 40. Therefore, the effect on reducing the leakage current of the device may be non-obvious. For this reason, in this embodiment, the first distance D1 may be set to be larger than or equal to 1.2 times the second distance D2.

Compared with the second distance D2, the first distance D1 should not be too large. When the first distance D1 is too large, the work function layers 210 that are farther from the protrusions 110 may have a weaker impact on the channels of the parasitic device. Also, when the first distance D1 is too large, it may be easy for the work function layers 210 to be difficult to fill the space between the adjacent protrusions 110, and also induce that the height of the device is too large.

For this reason, in this embodiment, the first distance D1 may be less than or equal to 3 times the second distance D2. That is, the first distance D1 may be larger than or equal to 1.2 times the second distance D2, and less than or equal to 3 times the second distance D2.

It should also be noted that in this embodiment, the distance between the adjacent channel structure layers 200 may be larger than the distance between the adjacent channel layers 40 in one channel structure layer 200. That is to say, the distance between adjacent channel structure layers 200 may be larger than the distance between adjacent channel layers 40 in one channel structure layer 200.

When the device is operating, the gate structure 230 may be used to control the turning on and off of the conductive channels. In this embodiment, the gate structure 230 may be a metal gate structure.

In this embodiment, the gate structure 230 may be located on the isolation layer 115 and cross the channel structure layer 200. The work function layers 210 may be used to adjust the work function of the gate structure 230, thereby adjusting the threshold voltage of the field effect transistor.

When forming an NMOS transistor, the material of the work function layers 210 may be a P-type work function material. That is, the work function of the material of the work function layers 210 may be closer to the top of the valence band of the material of the protrusions 110 and the plurality of channel layers 40, thereby increasing the threshold voltage of the NMOS device.

When forming a PMOS transistor, the material of the work function layers may be an N-type work function material. That is, the work function of the material of the work function layers 210 may be closer to the bottom of the conduction band of the material of the protrusions 110 and the plurality of channel layers 40, thereby increasing the threshold voltage of the PMOS device.

Moreover, in each gate-all-around transistor, the distance between the protrusions 110 and the channel layers 40 adjacent to the protrusions 110 may be larger than the distance between the adjacent channel layers 40, such that the thickness of the work function layers 210 filled between the protrusions 110 and the channel layers 40 adjacent to the protrusions 110 may be larger than the thickness of the work function layers 210 filled between the adjacent channel layers 40. In the semiconductor field, when the materials of the work function layers 210 are the same, usually when the work function layer 210 is thicker, the adjustment effect on the threshold voltage of the device is more obvious. When the thickness of the work function layers 210 filled between the protrusions 110 and the channel layers 40 adjacent to the protrusions 110 may be larger than the thickness of the work function layers 210 filled between the adjacent channel layers 40, compared with the device corresponding to the channel layers 40, the threshold voltage of the parasitic device corresponding to the protrusions 110 may be higher, and the parasitic device may be less likely to be turned on, which is beneficial to reducing the bottom leakage current generated in the protrusions 110 and improving the semiconductor structure performance.

In this embodiment, the material of the protrusions 110 and the plurality of channel layers 40 may include silicon. When forming an NMOS transistor, the work function of the material of the work function layers 210 may be 4.5 eV to 5.5 eV. When forming an NMOS transistor, the material of the work function layers 210 may include one or more of TiN, TaC, MON, Ta, TaN, TaSiN or TiSiN.

In this embodiment, when forming a PMOS transistor, the work function of the material of the work function layers 210 may be 3.9 eV to 4.3 eV. When forming a PMOS transistor, the material of the work function layers 210 may include one or more of TiAl, Al, TaAlN, TiAlN, TaCN or AlN.

In this embodiment, the gate structure 230 may further include a gate electrode layer 220 on the work function layers 210.

The gate electrode layer 220 may be used as an external electrode to realize electrical connection between the gate structure 230 and external circuits or other interconnection structures.

In this embodiment, the gate electrode layer 220 may be a metal gate electrode, and the material of the gate electrode layer 220 may be a metal material, such as W, Al, Cu, Ag, Au, Pt, Ni or Ti, etc.

It should be noted that in one embodiment, the gate structure 230 may also include: a covering layer (not shown) located between the work function layers 210 and the gate dielectric layer 240; and a barrier layer (not shown in the figure) located on the work function layers 210. The gate electrode layer 220 may be correspondingly located on the barrier layer. In some other embodiments, the gate structure may not include the covering layer and barrier layer.

The gate dielectric layer 240 may be used to achieve electrical isolation between the gate structure 230 and the conductive channels. In this embodiment, the gate dielectric layer 240 may be used to achieve electrical isolation between the work function layers 210 and the conductive channels. The material of the gate dielectric layer 240 may include one or more of silicon oxide, nitrogen-doped silicon oxide, HfO₂, ZrO₂, HfSiO, HfSiON, HfTaO, HfTiO, HfZrO, La₂O₃ or Al₂O₃.

In this embodiment, the gate dielectric layer 240 may include a high-k gate dielectric layer, and the material of the high-k gate dielectric layer may be a high-k dielectric material. The material of the high-k gate dielectric layer may be selected from ZrO₂, HfSiO, HfSiON, HfTaO, HfTiO, HfZrO or Al₂O₃. In other embodiments, the gate dielectric layer may include a gate oxide layer and a high-k gate dielectric layer located on the gate oxide layer.

A portion of the gate structure 230 located between adjacent channel layers 40 and between the protrusions 110 and the channel layers 40 adjacent to the protrusions 110 may serve as a first portion 230(1). Another portion of the gate structure 230 across the channel structure layer 200 may serve as a second portion 230(2). Along the extending direction of the channel structure layer 200, sidewalls of the first portion 230(1) and the second portion 230(2) may be indented relative to the ends of the plurality of channel layers 40.

In this embodiment, the semiconductor structure may further include: inner spacers 150 located on the sidewalls of the first portion 230(1), the inner spacers 150 exposing the ends of the channel structure layer 200 along the extension direction.

The inner spacers 150 may be used to achieve isolation between the source-drain doped regions 140 and the gate structure 230, and also increase the distance between the gate structure 230 and the source-drain doped regions 140, which is beneficial to reducing the parasitic capacitance between the gate structure 230 and the source-drain doped regions 140.

In this embodiment, the material of the inner spacers 150 may be an insulating material to achieve isolation between the gate structure 230 and the source-drain doping regions 140. In this embodiment, the material of the inner spacers 150 may include silicon nitride, silicon oxide, silicon oxynitride, a low-k dielectric material or an ultra-low-k dielectric material. As an example, the inner spacers 150 may be made of silicon nitride.

The semiconductor structure may further include gate spacers 165 located on the sidewalls of the second portion 230(2) and exposing the ends of the channel structure layer 200 along the extension direction. The gate spacers 165 may be used to define the formation positions of the source-drain doping regions, and may be also used to protect the sidewalls of the gate structure 230.

In this embodiment, the gate spacers 165 may be made of a material including silicon nitride, silicon oxide, silicon oxynitride, a low-k dielectric material or an ultra-low-k dielectric material. The gate spacers 165 may be a single layer structure or a stacked layer structure. As an example, the gate spacers 165 may be a single-layer structure, and the material of the gate spacers 165 may be silicon nitride.

The source-drain doping regions 140 may be used as the source or drain of the field-effect transistor. When the field-effect transistor is operating, the source-drain doping regions 140 may be used to provide a carrier source. In this embodiment, the source-drain doped regions 140 may be located on two sides of the gate structure 230, the gate spacers 165 and the inner spacers 150.

In this embodiment, each source-drain doped region 140 may include a stress layer doped with ions. The stress layer may be used to provide stress to the channel region, thereby improving carrier mobility. In one embodiment, when forming an NMOS transistor, one source-drain doped region 140 may include a stress layer doped with N-type ions, and the material of the stress layer may be Si or SiC. When forming a PMOS transistor, one source-drain doped region 140 may include a stress layer doped with P-type ions, and the material of the stress layer may be Si or SiGe.

In this embodiment, the semiconductor structure may further include: an interlayer dielectric layer 120 located on the isolation layers 115 on the sides of the gate structure 230. The interlayer dielectric layer 120 may cover the sidewalls of the gate spacers 165 and the source-drain doped regions 140.

The interlayer dielectric layer 120 may be used to isolate adjacent devices. In this embodiment, the material of the interlayer dielectric layer 120 may be silicon oxide. The material of the interlayer dielectric layer 120 may also be other insulating materials.

The present disclosure also provides a fabrication method of a semiconductor structure. FIG. 4 to FIG. 16 illustrate structures corresponding to certain stages of an exemplary fabrication method of a semiconductor structure provided by one embodiment of the present disclosure.

The fabrication method of the semiconductor structure provided by the present disclosure will be illustrated below with reference to the drawings.

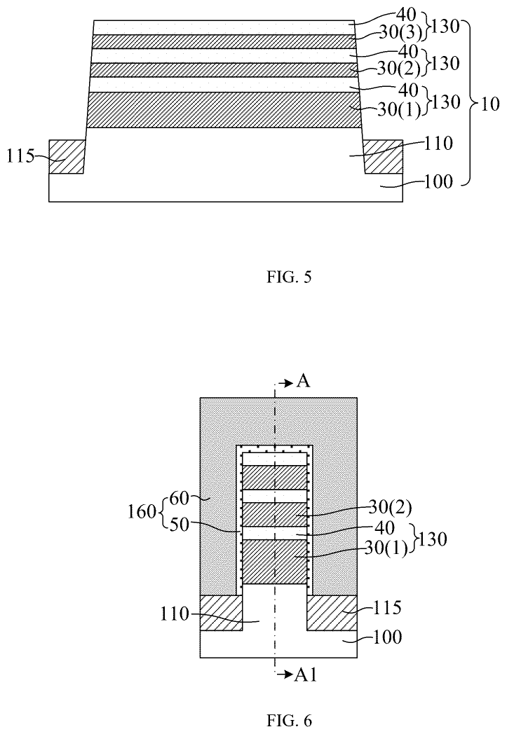

As shown in FIG. 4 which is a cross-sectional view along a direction perpendicular to an extending direction of channel layers and FIG. 5 which is a cross-sectional view along the A-A1 direction in FIG. 4, a base substrate 10 may be provided for forming MOS transistors. The base substrate 10 may include a substrate 100, discrete protrusions on the substrate 100, and a plurality of stacked channel stack layers 130 on each protrusion 110. Each channel stack layer 130 may include a sacrificial layer 30 and a channel layer 40 on the sacrificial layer 30. Sacrificial layers 30 between the protrusions 110 and channel layers 40 adjacent to the protrusions 110 may be used as first sacrificial layers 30(1), and sacrificial layers 30 in channel stack layers 130 above the first sacrificial layers 30(1) may be used as second sacrificial layers 30(2). The thickness of the first sacrificial layers 30(1) may be larger than the thickness of the second sacrificial layers 30(2).

The base substrate 10 may be used to provide a process platform for the formation of the semiconductor structure. In this embodiment, the base substrate 10 may be used to provide a process platform for forming a gate-all-around (GAA) transistor.

In this embodiment, the substrate 100 may be a silicon substrate, that is, the substrate 100 may be made of a material including single crystal silicon. In other embodiments, the substrate 100 may be made of a material including one or more of germanium, silicon germanium, silicon carbide, gallium nitride, gallium arsenide, or indium gallium. The substrate 100 may also be another type of substrate including a silicon-on-insulator substrate or germanium-on-insulator substrate.

In this embodiment, the protrusions 110 and the substrate 100 may have an integrated structure, and the protrusions 110 and the substrate 100 may be made of the same material, which is silicon. In other embodiments, the material of the protrusions may be different from the material of the substrate, and the material of the protrusions may be other suitable materials, such as one or more of germanium, silicon germanium, silicon carbide, gallium nitride, gallium arsenide or indium gallium.

The channel stack layers 210 may provide a process basis for the subsequent formation of channel layers 40 suspended and arranged at intervals. In one embodiment, the channel layers 40 may be used to provide a conductive channel of the field effect transistor, and the sacrificial layers 30 may be used to support the channel layers 40, thereby providing a process basis for the subsequent implementation of the spaced and suspended arrangement of the channel layers 40, and the sacrificial layer 30 may be also used to occupy space for subsequent formation of the gate structure.

In this embodiment, the base substrate 10 may be used to form an NMOS transistor, the material of the channel layers 40 may be Si, and the material of the sacrificial layers 30 may be SiGe. In the subsequent process of removing the sacrificial layers 30, the etching selectivity of SiGe and Si may be relatively high. Therefore, by setting the material of the sacrificial layers 30 to SiGe and the material of the channel layers 40 to Si, the removal process of the sacrificial layers may be effectively prevented from impacting the channel layers 40, thereby improving the quality of the channel layers 40 and the device performance.

In this embodiment, the channel layers 40 and the protrusions 110 may be made of the same material. In other embodiments, the channel layers 40 and the protrusions 110 may be made of different materials.

In other embodiments, when forming a PMOS transistor, to improve the performance of the PMOS transistor, SiGe channel technology may be used. The material of the channel layers may be SiGe and the material of the sacrificial layers may be Si. In other embodiments, the material of the channel layers may also be one or more of germanium, silicon carbide, gallium nitride, gallium arsenide, or indium gallium.

In one embodiment, the number of the channel stack layers 130 may be multiple, and the stacking direction of the plurality of channel stack layers 130 may be perpendicular to the surface of the substrate 100. In one embodiment, the number of the channel stack layers 130 may be three. In other embodiments, the number of the channel stack layers may be two, four, five, etc.

The thickness of the first sacrificial layers 30(1) may be larger than the thickness of the second sacrificial layers 30(2). When subsequently removing the sacrificial layers 30 to form through grooves, the first sacrificial layers 30(1) may be removed to form first through grooves, and the second sacrificial layers 30(2) may be removed to form second through grooves. The height of the first through grooves may be larger than the height of the second through grooves. Therefore, when forming work function layers in the through grooves, the thickness of the work function layers filled in the first through grooves may be larger than the thickness of the work function layers 210 filled in the second through grooves.

It should be noted that the thickness of the first sacrificial layers 30(1) may be larger than the thickness of the second sacrificial layers 30(2), and the difference between the thickness of the first sacrificial layers 30(1) and the thickness of the second sacrificial layers 30(2) should not be too small. Otherwise, the difference of the height of the subsequently formed first through grooves and second through grooves may be too small. The difference of the thickness between the work function layers filled in the first through grooves and the work function layers 210 filled in the second through grooves may be non-obvious. The work function layers may not have a significant effect on adjusting the threshold voltage of the parasitic device corresponding to the protrusions 110, which is not able to make the threshold voltage of the parasitic device significantly larger than the threshold voltage of the device corresponding to the plurality of channel layers 40. Therefore, the effect on reducing the leakage current of the device may be non-obvious. For this reason, in this embodiment, the thickness of the first sacrificial layers 30(1) may be set to be larger than or equal to 1.2 times the thickness of the second sacrificial layers 30(2).

The thickness of the first sacrificial layers 30(1) should not be too large compared with the thickness of the second sacrificial layers 30(2). When the thickness of the first sacrificial layers 30(1) is too large, the work function layers that are farther from the protrusions 110 may have a weaker impact on the channels of the parasitic device when subsequently forming the second through grooves and the work function layers filled in the second through grooves, and also, it may be easy for the height of the second through grooves to be too large and the work function layers to be difficult to fill the second through grooves. And also, the height of the device may be too large.

For this reason, in this embodiment, the thickness of the first sacrificial layers 30(1) may be less than or equal to 3 times the thickness of the second sacrificial layers 30(2). That is, the thickness of the first sacrificial layers 30(1) may be larger than or equal to 1.2 times the thickness of the second sacrificial layers 30(2), and less than or equal to 3 times the thickness of the second sacrificial layers 30(2).

In this embodiment, the material of the sacrificial layers 30 may include SiGe, and the germanium concentration in the second sacrificial layers 30(2) may be larger than the germanium concentration in the first sacrificial layers 30(1). In this embodiment, compared with the first sacrificial layers 30(1), the second sacrificial layers 30(2) may be thinner, and subsequent removal of the second sacrificial layers 30(2) may be more difficult than removing the first sacrificial layers 30(1). By making the germanium concentration in the second sacrificial layers 30(2) larger than the germanium concentration in the first sacrificial layers 30(1), the removal rate of the second sacrificial layers 30(2) may be increased during subsequent removal of the sacrificial layers 30.

As shown in FIG. 4 and FIG. 5, after providing the base substrate 10 and before forming a dummy gate structure, the method may further include: forming an isolation layer 115 on the substrate 100 and surrounding the protrusions 110. The isolation layer 115 may expose the channel stack layers 130.

The isolation layer 115 may be used to isolate adjacent protrusions 110 and also to isolate the substrate 100 and a gate structure. In this embodiment, the isolation layer 115 may be made of silicon oxide. In some other embodiments, the isolation layer 115 may be made of another insulating material including one or more of silicon oxide, silicon nitride, silicon oxynitride, or silicon germanium oxide.

In one embodiment, the top surface of the isolation layer 115 may be lower than the top surfaces of the protrusions 110. In other embodiments, the top surface of the isolation layer may be flush with the top surfaces of the protrusions.

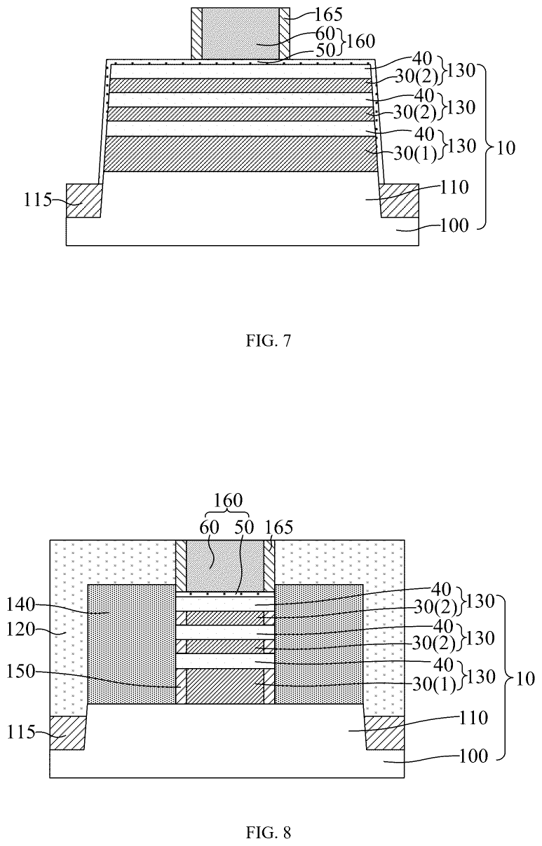

As shown in FIG. 6 which is a cross-sectional view based on FIG. 4 and FIG. 7 which is a cross-sectional view along the A-A1 direction in FIG. 5, a dummy gate structure 160 crossing the channel stack layers 130 may be formed.

The dummy gate structure 160 may be formed on the isolation layer 110 and cross the channel stack layers 130. The dummy gate structure 160 may cover a portion of tops and a portion of sidewalls of the channel stack layers 130. The dummy gate structure 160 may have an extending direction perpendicular to the extending direction of the channel stack layers 130.

The dummy gate structure 160 may be used to occupy a space for subsequently forming a gate structure.

The dummy gate structure 160 may be a stacked structure or a single-layer structure. In this embodiment, the dummy gate structure 160 may be a stacked structure, including a dummy gate oxide layer (not shown) and a dummy gate layer (not shown) located on the dummy gate oxide layer. The dummy gate structure 160 may be a polysilicon gate structure, the material of the dummy gate oxide layer may be silicon oxide or silicon oxynitride, and the material of the dummy gate layer may be polysilicon.

In this embodiment, after forming the dummy gate structure 160, the fabrication method of the semiconductor structure may further include: forming gate spacers 165 on the sidewalls of the dummy gate structure 160.

The gate spacers 165 may be used together with the dummy gate structure 160 as an etching mask for the subsequent etching process of forming trenches, to define the formation positions of the source-drain doping regions, and may be also used to protect the sidewalls of the dummy gate structure 160 and the subsequent gate structure.

In this embodiment, the gate spacers 165 may be made of a material including silicon nitride, silicon oxide, silicon oxynitride, a low-k dielectric material or an ultra-low-k dielectric material. The gate spacers 165 may be a single layer structure or a stacked layer structure. As an example, the gate spacers 165 may be a single-layer structure, and the material of the gate spacers 165 may be silicon nitride.

As shown in FIG. 8, in one embodiment, after forming the dummy gate structure 160 and before removing the dummy gate structure 160, the fabrication method of the semiconductor structure may further include: forming source-drain doped layers 140 in the channel stack layers 130 on two sides of the dummy gate structure 160. The source-drain doped layers 140 may contact ends of each channel layers 40 in the channel stack layers 130 along the extending direction.

The source-drain doping regions 140 may be used as the source or drain of the field-effect transistor. When the field-effect transistor is operating, the source-drain doping regions 140 may be used to provide a carrier source.

In this embodiment, each source-drain doped region 140 may include a stress layer doped with ions. The stress layer may be used to provide stress to the channel region, thereby improving carrier mobility. In one embodiment, when forming an NMOS transistor, one source-drain doped region 140 may include a stress layer doped with N-type ions, and the material of the stress layer may be Si or SiC. When forming a PMOS transistor, one source-drain doped region 140 may include a stress layer doped with P-type ions, and the material of the stress layer may be Si or SiGe.

As shown in FIG. 8, an interlayer dielectric layer 120 may be formed on the isolation layer 115 exposed by the dummy gate structure 160. The interlayer dielectric layer 120 may cover the sidewalls of the gate spacers 165 and the source-drain doped regions 140.

The interlayer dielectric layer 120 may be used to isolate adjacent devices. In this embodiment, the material of the interlayer dielectric layer 120 may be silicon oxide. The material of the interlayer dielectric layer 120 may also be other insulating materials.

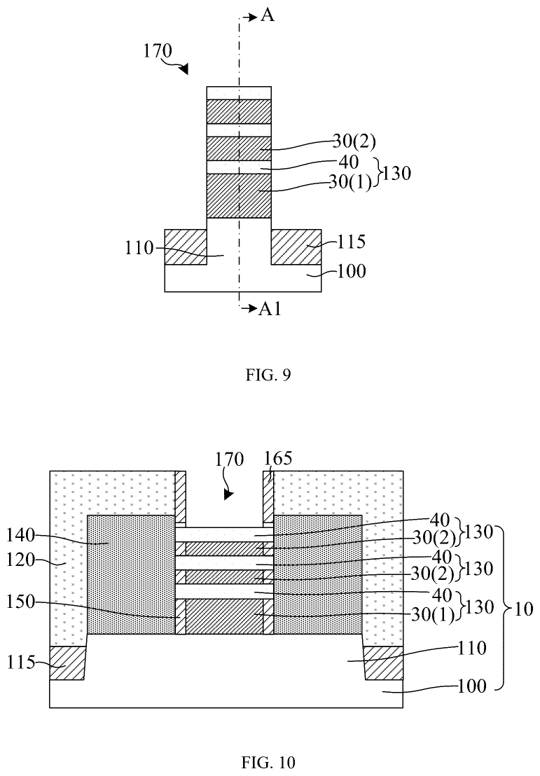

As shown in FIG. 9 which is a cross-sectional view at the gate opening along a direction perpendicular to the extending direction of the channel stack layers 130 and FIG. 10 which is a cross-sectional view along the A-A1 direction in FIG. 9, the dummy gate structure 160 may be removed to form a gate opening 170 exposing the channel stack layers 130.

The gate opening 170 may be used to provide a spatial location for forming the gate structure. The gate opening 170 may expose the channel stack layers 130 for subsequent removal of the sacrificial layers 30 in the channel stack layers 130 through the gate opening 170.

In this embodiment, the bottom of the gate opening 170 may also expose the isolation layer 115.

In one embodiment, when removing the dummy gate structure 160, the gate opening 170 may be formed in the interlayer dielectric layer 120.

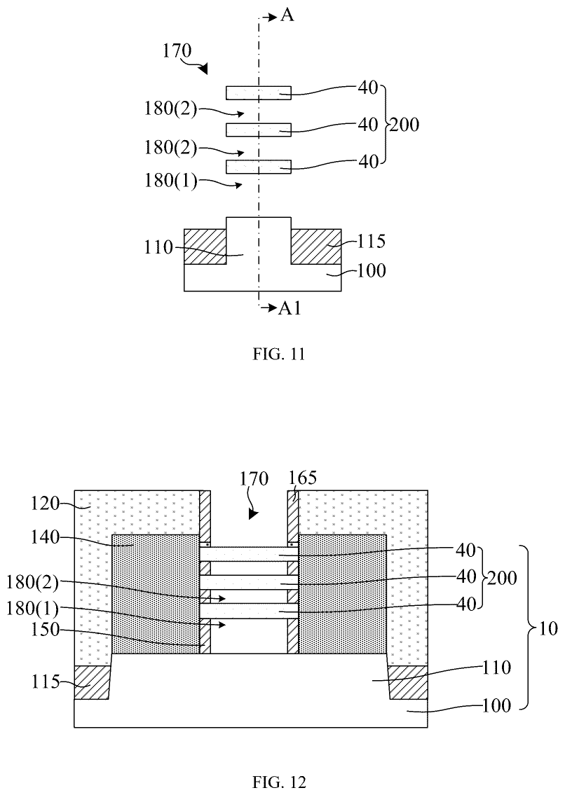

As shown in FIG. 11 which is a cross-sectional view based on FIG. 9 and FIG. 12 which is a cross-sectional view along the A-A1 direction in FIG. 9, the sacrificial layers 30 in the channel stack layers 130 may be removed to form through grooves 180 connected to the gate opening 170. The through grooves 180 may include first through grooves 180(1) formed by removing the first sacrificial layers 30(1) and second through grooves 180(2) formed by removing the second sacrificial layers 30(2).

The through grooves 180 and the gate opening 170 may jointly provide a spatial location for forming the gate structure. The through grooves 180 may be connected with the gate opening 170.

In this embodiment, the thickness of the first sacrificial layers 30(1) may be larger than the thickness of the second sacrificial layers 30(2). Therefore, when removing the first sacrificial layers 30(1) to form the first through grooves 180(1) and removing the second sacrificial layers 30(2) to form the second through grooves 180(2), the height of the first through grooves 180(1) may be larger than the height of the second through grooves 180(2).

In this embodiment, after the sacrificial layers 30 are removed, the channel layers 40 may be spaced apart from the protrusions 110, and adjacent channel layers 40 may be arranged at intervals. The plurality of channel layers 40 arranged at intervals may be used to form a channel structure layer 200.

In this embodiment, the material of the sacrificial layers 30 may include SiGe, and the process of removing the sacrificial layers 30 may include a wet etching process. The wet etching process has isotropic etching characteristics, which may facilitate the removal of each sacrificial layer 30 completely.

In this embodiment, compared with the first sacrificial layers 30(1), the second sacrificial layers 30(2) may be thinner, and subsequent removal of the second sacrificial layers 30(2) may be more difficult than removing the first sacrificial layers 30(1). By making the germanium concentration in the second sacrificial layers 30(2) larger than the germanium concentration in the first sacrificial layers 30(1), the removal rate of the second sacrificial layers 30(2) may be increased during subsequent removal of the sacrificial layers 30, and also the residual of the second sacrificial layers 30(2) may be reduced.

In one embodiment, the wet etching process may use an etching solution or etching vapor including HCl.

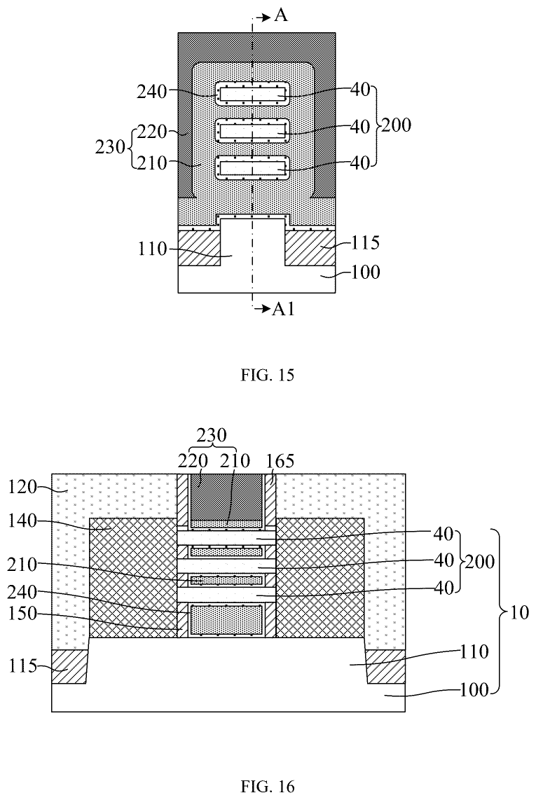

As shown in FIG. 13 to FIG. 15 which is cross-sectional views and FIG. 16 which is a cross-sectional view along the A-A1 direction in FIG. 15, a gate structure 230 may be formed in the gate opening 170 and the through grooves 180. The gate structure 230 may include work function layers 210 surrounding the surfaces of the channel layers 140 and filled in the through holes 180.

When the device is operating, the gate structure 230 may be used to control the turning on and off of the conductive channels. In this embodiment, the gate structure 230 may be a metal gate structure.

The work function layers 210 may be used to adjust the work function of the gate structure 230, thereby adjusting the threshold voltage of the field effect transistor.

When forming an NMOS transistor, the material of the work function layers 210 may be a P-type work function material. That is, the work function of the material of the work function layers 210 may be closer to the top of the valence band of the material of the protrusions 110 and the plurality of channel layers 40, thereby increasing the threshold voltage of the NMOS device.

When forming a PMOS transistor, the material of the work function layers may be an N-type work function material. That is, the work function of the material of the work function layers 210 may be closer to the bottom of the conduction band of the material of the protrusions 110 and the plurality of channel layers 40, thereby increasing the threshold voltage of the PMOS device.

Further, the height of the first through holes 180(1) may be larger than the height of the second through grooves 180(2). Therefore, the thickness of the work function layers 210 filled in the first through grooves 180(1) may be larger than the thickness of the work function layers 210 filled in the second through grooves 180(2). In the semiconductor field, when the materials of the work function layers 210 are the same, usually when the work function layer 210 is thicker, the adjustment effect on the threshold voltage of the device is more obvious. When the thickness of the work function layers 210 filled in the first through grooves 180(1) may be larger than the thickness of the work function layers 210 filled in the second through grooves 180(2), compared with the device corresponding to the channel layers 40, the threshold voltage of the parasitic device corresponding to the protrusions 110 may be higher, and the parasitic device may be less likely to be turned on, which is beneficial to reducing the bottom leakage current generated in the protrusions 110 and improving the semiconductor structure performance.

In this embodiment, the material of the protrusions 110 and the plurality of channel layers 40 may include silicon. When forming an NMOS transistor, the work function of the material of the work function layers 210 may be 4.5 eV to 5.5 eV.

When forming an NMOS transistor, the material of the work function layers 210 may include one or more of TiN, TaC, MON, Ta, TaN, TaSiN or TiSiN.

In this embodiment, when forming a PMOS transistor, the work function of the material of the work function layers 210 may be 3.9 eV to 4.3 eV.

When forming a PMOS transistor, the material of the work function layers 210 may include one or more of TiAl, Al, TaAlN, TiAlN, TaCN or AlN.

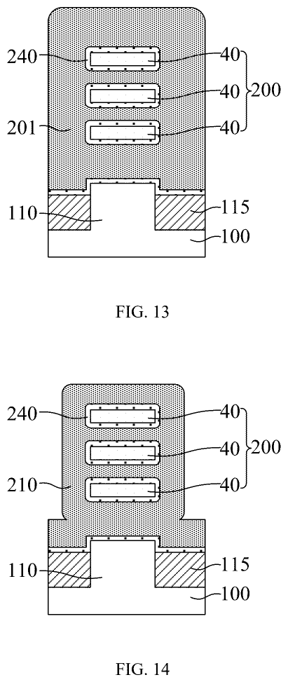

In this embodiment, forming the work function layers 210 may include: as shown in FIG. 13, forming a work function film 201 surrounding the surfaces of the channel layers 40 exposed by the gate opening 170 and the through grooves 180, where the work function film 201 is filled in the through grooves 180; and as shown in FIG. 14, removing a portion of the thickness of the work function film 201 on the sidewalls of the channel layers 40 exposed by the gate opening 170 and on the top of the channel layers 40 farthest from the substrate 100. The remaining portion of the work function film 201 may be used as the work function layers 210.

By first forming the work function film 201 filled in the through grooves 180 and then etching the portion of the work function film on the sidewalls of the channel layers 40 exposed by the gate opening 170 and on the tops of the channel layers 40 farthest from the substrate 100, the work function layer 210 may be ensured to fill the first through grooves 180 (1) and the second through grooves 180(2), and also the channel layers 40 located on the sides of the channel layers 40 exposed by the gate opening 170 and on the sidewalls and on tops of the channel layers 40 farthest from the substrate 100 may be ensured to have a thickness meeting process requirements.

As an example, the process of forming the work function film 201 may include an atomic layer deposition process. The atomic layer deposition process has strong gap filling ability and conformal coverage ability, which is beneficial to filling the work function film 201 in the through grooves 180 and is also beneficial to improving the formation quality of the work function film 201.

In this embodiment, an isotropic etching process may be used to remove the portion of the thickness of the work function film 201 on the sidewalls of the channel layers 40 exposed by the gate opening 170 and on the top of the channel layers 40 farthest from the substrate 100. The isotropic etching process has the characteristics of isotropic etching, thereby being able to etching the portion of the work function film on the sidewalls of the channel layers 40 exposed by the gate opening 170 and on the tops of the channel layers 40 farthest from the substrate 100, to reduce the thickness of the work function film 201 at the location.

In this embodiment, the gate structure 230 may further include a gate electrode layer 220 on the work function layers 210 and filling the gate opening 170. The gate electrode layer 220 may be used as an external electrode to realize electrical connection between the gate structure 230 and external circuits or other interconnection structures.

In this embodiment, the gate electrode layer 220 may be a metal gate electrode, and the material of the gate electrode layer 220 may be a metal material, such as W, Al, Cu, Ag, Au, Pt, Ni or Ti, etc.

As shown in FIG. 15 and FIG. 16, after forming the work function layers 210, the gate electrode layer 220 may be formed on the work function layers 210 and filling the gate opening 170.

In one embodiment, the fabrication method of the semiconductor structure may further include: after forming the gate opening 170 and the through grooves 180, and before forming the gate structure 230, forming a gate dielectric layer 240 on the surfaces of the channel layers 40 exposed by the gate opening 170 and the through grooves 180.

The gate dielectric layer 240 may be used to achieve electrical isolation between the gate structure 230 and the conductive channels. In this embodiment, the gate dielectric layer 240 may be used to achieve electrical isolation between the work function layers 210 and the conductive channels. The material of the gate dielectric layer 240 may include one or more of silicon oxide, nitrogen-doped silicon oxide, HfO₂, ZrO₂, HfSiO, HfSiON, HfTaO, HfTiO, HfZrO, La₂O₃ or Al₂O₃.

In this embodiment, the gate dielectric layer 240 may include a high-k gate dielectric layer, and the material of the high-k gate dielectric layer may be a high-k dielectric material. The material of the high-k gate dielectric layer may be selected from ZrO₂, HfSiO, HfSiON, HfTaO, HfTiO, HfZrO or Al₂O₃. In other embodiments, the gate dielectric layer may include a gate oxide layer and a high-k gate dielectric layer located on the gate oxide layer.

In one embodiment, the gate structure 230 may also include: a covering layer (not shown) located between the work function layers 210 and the gate dielectric layer 240; and a barrier layer (not shown in the figure) located on the work function layers 210. The gate electrode layer 220 may be correspondingly located on the barrier layer. In some other embodiments, the gate structure may not include the covering layer and barrier layer.

The embodiments disclosed herein are exemplary only. Other applications, advantages, alternations, modifications, or equivalents to the disclosed embodiments are obvious to those skilled in the art and are intended to be encompassed within the scope of the present disclosure.

1. A semiconductor structure, comprising:
a substrate; and
gate-all-around transistors on the substrate, wherein:
each gate-all-around transistor includes:
a discrete protrusion on the substrate;
a channel structure layer spaced apart from and suspended on the protrusion, wherein the channel structure layer includes a plurality of channel layers arranged at intervals; the plurality of channel layers is longitudinally stacked along a direction perpendicular to a surface of the substrate; and a distance between the protrusion and a channel layer adjacent to the protrusion is larger than a distance between adjacent channel layers along the direction perpendicular to the surface of the substrate;
a gate structure crossing the channel structure layer and surrounding each channel layer in the channel structure layer, wherein: the gate structure includes work function layers surrounding surfaces of the plurality of channel layers; the work function layers are filled between the protrusion and the channel layer adjacent to the protrusion, and between the adjacent channel layers;
a gate dielectric layer between the gate structure and the plurality of channel layers and between the gate structure and the protrusion; and
source-drain doped regions on the protrusion at two sides of the gate structure, wherein the source-drain doped regions contact ends of each channel layer in the channel structure layer along an extension direction.

2. The semiconductor structure according to claim 1, wherein:
the plurality of channel layers is made of a material same as a material of the protrusion.

3. The semiconductor structure according to claim 1, wherein:
along the direction perpendicular to the surface of the substrate, the distance between the protrusion and the channel layer adjacent to the protrusion is a first distance, and the distance between the adjacent channel layers is a second distance; and
the first distance is larger than or equal to 1.2 times the second distance, and less than or equal to 3 times the second distance.

4. The semiconductor structure according to claim 1, wherein:
the protrusion and the plurality of channel layers are made of a material including silicon; and
the gate-all-around transistors include an NMOS transistor and/or a PMOS transistor,
a work function of a material of the work function layers for the NMOS transistor is 4.5 eV to 5.5 eV; and
a work function of a material of the work function layers for the PMOS transistor is 3.9 eV to 4.3 eV.

5. The semiconductor structure according to claim 1, wherein:
the gate-all-around transistors include an NMOS transistor and/or a PMOS transistor,
the material of the work function layers for the NMOS transistor includes one or more of TiN, TaC, MON, Ta, TaN, TaSiN, or TiSiN; and the material of the work function layers for the PMOS transistor includes one or more of TiAl, Al, TaAlN, TiAlN, TaCN or AIN.

6. The semiconductor structure according to claim 1, further including:
an isolation layer on the substrate and surrounding the protrusion; and
an interlayer dielectric layer on the isolation layer at sides of the gate structure, wherein: the gate structure is located on the isolation layer and crossing the channel structure layer; a portion of the gate structure between the adjacent channel layers and between the protrusion and the channel layer adjacent to the protrusion is a first portion; and another portion of the gate structure crossing the channel structure layer is a second portion; along the extension direction of the channel structure layer, the sidewalls of the first portion and the second portion are indented relative to the ends of the plurality of channel layers;
inner spacers located on the sidewalls of the first portion and exposing the ends of the channel structure layer along the extension direction; and
gate spacers located on the sidewalls of the second portion and exposing the ends of the channel structure layer along the extension direction, wherein the source-drain doped regions are located on two sides of the gate structure, the gate spacers and the inner spacers.

7. The semiconductor structure according to claim 1, wherein:
a distance between one channel structure layer and another channel structure layer is larger than a distance between one channel layer and another channel layer in a same channel structure layer.

8. The semiconductor structure according to claim 1, wherein:
the gate structure further includes: a covering layer located between the work function layers and the gate dielectric layer; a barrier layer located on the work function layers; and a gate electrode layer located on the barrier layer.

9. The semiconductor structure according to claim 1, wherein:
the substrate is made of a material including one or more of single crystal silicon, germanium, silicon germanium, silicon carbide, gallium nitride, gallium arsenide, or indium gallium;
the plurality of channel layers and the protrusion are made of a material including one or more of single crystal silicon, germanium, silicon germanium, silicon carbide, gallium nitride, gallium arsenide or indium gallium; and
the gate dielectric layer is made of a material including one or more of HfO₂, ZrO₂, HfSiO, HfSiON, HfTaO, HfTiO, HfZrO, La₂O₃, Al₂O₃, silicon oxide, or nitrogen-doped silicon oxide.

10. A fabrication method of a semiconductor structure, comprising:
providing a base substrate for forming transistors, wherein:
the base substrate includes a substrate, discrete protrusions on the substrate; and a plurality of channel stack layers stacked on each protrusion;
each channel stack layer includes a sacrificial layer and a channel layer on the sacrificial layer;
sacrificial layers between the protrusion and a channel stack layer adjacent to the protrusion are used as first sacrificial layers; and
sacrificial layers in channel stack layers above the first sacrificial layers are used as second sacrificial layers;
a thickness of the first sacrificial layers is larger than a thickness of the sacrificial layers,
forming a dummy gate structure crossing the plurality of channel stack layers;
forming source-drain doped regions in the channel stack layers on two sides of the dummy gate structure, wherein the source-drain doped regions contact ends of each channel layer in the plurality of channel stack layers along the extending direction;
after forming the source-drain doped regions, removing the dummy gate structure to form a gate opening exposing the plurality of channel stack layer;
removing the sacrificial layers in the plurality of channel stack layers, to form through grooves connected to the gate opening, wherein the through grooves include first through grooves formed by removing the first sacrificial layers and second through grooves formed by removing the second sacrificial layers; and
forming a gate structure in the gate opening, wherein: the gate structure includes work function layers surrounding surfaces of channel layers and filled in the through grooves.

11. The fabrication method of the semiconductor structure according to claim 10, wherein:
the channel layers are made of a material same as a material of the protrusions.

12. The fabrication method of the semiconductor structure according to claim 10, wherein:
a thickness of the first sacrificial layers is larger than or equal to 1.2 times a thickness of the second sacrificial layers, and less than or equal to 3 times the thickness of the second sacrificial layers.

13. The fabrication method of the semiconductor structure according to claim 10, wherein:
the sacrificial layers are made of a material including SiGe, and Ge concentration in the second sacrificial layers is larger than Ge concentration in the first sacrificial layers.

14. The fabrication method of the semiconductor structure according to claim 10, wherein:
the work function layers are formed by an atomic layer deposition process.

15. The fabrication method of the semiconductor structure according to claim 10, wherein:
the protrusions and the channel layers are made of a material including silicon;
when forming an NMOS transistor, a work function of a material of the work function layers is 4.5 eV to 5.5 eV; and
when forming a PMOS transistor, a work function of a material of the work function layers is 3.9 eV to 4.3 eV.

16. The fabrication method of the semiconductor structure according to claim 10, wherein:
the sacrificial layers are made of a material including SiGe, and are removed by a wet etching process.

17. The fabrication method of the semiconductor structure according to claim 10, wherein:
after providing the base substrate and before forming the dummy gate structure, the method further includes: forming an isolation layer on the substrate and surrounding the protrusions, wherein the isolation layer exposes the channel stack layers;
after forming the source-drain doped region and before removing the dummy gate structure, the method further includes: forming an interlayer dielectric layer on the isolation layer exposed by the dummy gate structure, wherein the interlayer dielectric layer covers the source-drain doped regions; and
when removing the dummy gate structure, the gate opening is formed in the interlayer dielectric layer.

18. The fabrication method of the semiconductor structure according to claim 10, wherein:
forming the work function layers includes: forming a work function film surrounding the gate opening and the surfaces of the channel layers exposed by the through grooves, and filled in the through grooves; and
removing a portion of the thickness of the work function film on sidewalls of the channel layers exposed by the gate opening and on the top of the channel layers farthest from the substrate, to use a remaining portion of the work function film as the work function layers.

19. The fabrication method of the semiconductor structure according to claim 10, after forming the gate opening and the through grooves, and before forming the gate structure, further including:
forming a gate dielectric layer on the surfaces of the channel layers exposed by the gate opening and the through grooves.

20. The fabrication method of the semiconductor structure according to claim 10, wherein:
the gate structure further includes a gate electrode layer on the work function layers and filled in the gate opening.
